(19) United States
(12) Patent Application Publication
(10) Pub. No.: US 2009/0253273 A1
(43) Pub. Date: Oct. 8, 2009

(54) METHOD OF HEAT-TREATING SEMICONDUCTOR

(75) Inventors: Naoki Sano, Yokohama-shi (JP); Toshiyuki Sameshima, Fuchu-shi (JP)

Correspondence Address: DITTHAVONG MORI & STEINER, P.C., 918 Prince St., Alexandria, VA, 22314, US

(73) Assignee: Hightec Systems Corporation, Yokohama-shi (JP)

(21) Appl. No.: 12/305,180

(22) PCT Filed: Apr. 25, 2007
(86) PCT No.: PCT/JP2007/058958

§ 371 Date: Dec. 16, 2008

(30) Foreign Application Priority Data
Jun. 21, 2006 (JP) 2006-171790

(51) Int. Cl. H01L 21/268

(52) U.S. Cl. 438/795; 257/E21.347

(57) ABSTRACT

The present invention relates to a method of heat-treating a semiconductor, and the object is to enable heat-treating to a semiconductor or semiconductor device in a short period time and to obtain a stable and high reforming effect. The present invention is a method in which carbon or a layer including carbon is provided as a light absorbing layer, and a semiconductor material as a heat-treating target layer or semiconductor device contacting the heat absorbing layer directly or through a heat transfer layer of 5 nm-100 μm in thickness is heat-treated, and the light source to be used is a semiconductor laser light of wavelength of 600 nm-2 μm, and this semiconductor laser light is caused to continuously irradiate and sweep the surface of the heat-treating target material. The light source can be easily made to output high power, and heat-treating at a high speed and with low energy consumption is realized.

### TECHNICAL FIELD

The present invention relates to a method of heat-treating materials to be processed, and in particular relates to a method of heat-treating semiconductor materials and devices efficiently in a short period of time.

### BACKGROUND ART

In manufacture of semiconductor devices, such as various types of semiconductor elements including bipolar transistors and insulated gate field effect transistors (MOS-type transistors), semiconductor integrated circuits, etc., heat-treating is often carried out, for example in repairing crystal defects of a semiconductor, activating introduced impurities, phase-changing from an amorphous material to a crystal, etc.

In particular, for a thin-film transistor that is formed on an insulating body or insulating film, the crystallization technology therefore is important. As conventional thin-film crystallization techniques, a method of heating at a high temperature from 600° C. to 1000° C. for 2 to 20 hours has been known (see, for example, Patent Document 1).

Or, a technique of melting a semiconductor thin film for a short period of time using a pulse laser so as to be solidified and crystallized, and a technique of carrying out laser-annealing while suppressing a ridge that is generated on the semiconductor surface have been known (see, for example, Patent Document 2).

These crystallization techniques are the methods used for forming a polycrystalline silicon film of good quality over a large area.

### Patent Document 1: Japanese Unexamined Patent Application Publication No. 2001-210631

### Patent Document 2: Japanese Unexamined Patent Application Publication No. 2004-311615

### DISCLOSURE OF THE INVENTION

However, in the technique disclosed in Patent Document 1, etc., there are problems that heating at a high temperature for a long period of time is necessary, energy consumption is large, the manufacture time is long, and the manufacturing cost is high.

On the other hand, in the method of using a semiconductor laser light as in the technique described in Patent Document 2, there is a problem that energy loss due to light reflection on the surface of the silicon thin film semiconductor is large.

Further, as a prior art, a method has been proposed, in which a heating layer that is consisted of a carbon layer or a layer including carbon and that generates heat by absorbing light is heated by pulse-like light irradiation, and thereby a silicon film is indirectly heated. However, in this prior art, although it is an effective means for solving the above-described problems, when pulse light irradiation is extremely short, due to adiabatic reaction, there is a case that heat transmission turns out to be disrupted due to breaking of a thin film containing carbon, which is called ablation.

The object of the present invention is to provide a method of heat-treating that enables instantaneous heat-treating to a semiconductor or semiconductor device and that is capable of improving the problem of light energy loss.

To achieve the above-described object, the invention of claim 1 is characterized in that in a method of heat-treating a semiconductor material contacting, directly or through a heat-transfer layer of 5 nm-100 μm in thickness, a heating layer constituted of a carbon layer or layer including carbon that produces heat by absorbing light energy, by heating the heating layer, the light source to be used is a semiconductor laser light in a range of wavelength of 600 nm-2 μm, and by causing the semiconductor laser light to continuously irradiate and sweep the heating layer constituted of a carbon layer or layer including carbon, the same place of the heating layer is light-irradiated for a time period of 100 ns-100 ms, and the semiconductor laser light is caused to repeatedly sweep and irradiate a place to be swept and irradiated so that the place to be swept and irradiated has a partial overlap, and thereby a desired area of the semiconductor material is heat-treated.

The invention of claim 2 is characterized in that the semiconductor laser light described in claim 1 is caused to sweep and irradiate with the light intensity thereof controlled.

The invention of claim 3 is characterized in that in a method of heat-treating a semiconductor material contacting, directly or through a heat-transfer layer of 5 nm-100 μm in thickness, a heating layer constituted of a carbon layer or layer including carbon that produces heat by absorbing light energy, by causing a semiconductor laser light in a range of wavelength of 600 nm-2 μm to irradiate the heating layer to cause the heating layer to produce heat, the semiconductor laser light is caused to continuously irradiate the same place of the heating layer for a time period of 100 ns-100 ms for one sweeping, and the same place is repeatedly swept with the light intensity of the irradiating semiconductor laser light changed.

The invention of claim 4 is characterized in that in a method of heat-treating a semiconductor material contacting, directly or through a heat-transfer layer of 5 nm-100 μm in thickness, a heating layer constituted of a carbon layer or layer including carbon that produces heat by absorbing light energy, by causing a semiconductor laser light in a range of wavelength of 600 nm-2 μm to irradiate the heating layer to cause the heating layer to produce heat, the semiconductor laser light consisting of a plurality of beams is caused to sweep and irradiate.

The invention of claim 5 is characterized in that in claim 4, the semiconductor laser light consisting of a plurality of beams is arranged in the same direction as the beam sweeping direction, and the light intensities of the plurality of beams are differentiated and the same place is sequentially irradiated with laser beams of different intensities.

The invention of claim 6 is characterized in that in claim 5, the intensity of a beam irradiating first is weaker than the intensity of a beam irradiating later.

The invention of claim 7 is characterized in that the semiconductor laser light consisting of a plurality of beams is arranged perpendicularly to the beam sweeping direction.

The invention of claim 8 is characterized in that the semiconductor laser light is beam-shaped by a predetermined optical system so as to be a linear beam perpendicularly to the beam sweeping direction.

The invention of claim 9 is characterized in that the semiconductor laser light described in claim 1 is caused to irradiate the heating layer through a filter of spatial modulation type or a light shielding mask covering a part of the beam sweeping area.

The invention of claim 10 is characterized in that in the method of heat-treating a semiconductor described in claim 1, the heating layer consisting of a carbon layer or layer including carbon is formed in a pattern shape on the semiconductor material.

The invention of claim 11 is characterized in that raw materials forming the carbon layer or layer including carbon described in claim 1 are in a particulate form.

The invention of claim 12 is characterized in that the material to be heat-treated described in claim 1 is formed in a substrate formed of a material having transparency relative to an irradiation light source, and the semiconductor laser light is caused to irradiate from the substrate side.

The invention of claim 13 is characterized in that a semiconductor laser light in a range of wavelength of 600 nm-2 μm is caused to irradiate a heating layer constituted of a carbon layer or layer including carbon that produces heat by absorbing light energy, to cause the heating layer to produce heat to heat-treat a semiconductor material through an impurities containing layer of 5 nm-100 μm in thickness contacting the heating layer, and the semiconductor laser light is caused to irradiate the same place of the heating layer continuously for a time period of 100 ns-100 ms.

The invention of claim 14 is characterized in that in the method of heat-treating a semiconductor described in claim 1, the semiconductor material is temperature-controlled by a heating or cooling means that is separate from the laser irradiation.

The invention of claim 15 is characterized in that in the method of heat-treating a semiconductor described in claim 13, the semiconductor material is temperature-controlled by a heating or cooling means that is separate from the laser irradiation.

The invention of claim 16 is characterized in that in the method of heat-treating a semiconductor described in claim 1, at a time of the laser light irradiation, inactive gas is blown to the surface of the carbon layer that produces heat by absorbing light energy.

The invention of claim 17 is characterized in that in the method of heat-treating a semiconductor described in claim 13, at a time of the laser light irradiation, inactive gas is blown to the surface of the carbon layer that produces heat by absorbing light energy.

The invention of claim 18 is characterized in that in the method of heat-treating a semiconductor described in claim 1, heat-treating to the semiconductor material is a post-annealing process after ion implanting impurities into the semiconductor material.

By using the heat-treating method of the present invention, stable heat-treating with low energy consumption and processing in a short period of time can be realized.

It is needless to say that with this heat-treating, phase-shifting from an amorphous semiconductor to a crystalline semiconductor, activation of impurities, recovery of crystallinity, formation of a pn junction, reforming of an insulating film in MOS-type transistors, etc., or the like can be accomplished.

### BRIEF DESCRIPTION OF THE DRAWINGS

FIG. 1 is a diagram illustrating a basic configuration of the present invention.

FIG. 2 is a diagram illustrating an example of a pattern of light sweeping in the present invention.

FIG. 3 is a diagram illustrating an example of a pattern of light sweeping in the present invention.

FIG. 4 is a diagram illustrating an example of a method of sweeping with a plurality of laser beams, in the present invention.

FIG. 5 is a diagram illustrating an example of a method of sweeping with a laser beam that has plural and different outputs, in the present invention.

FIG. 6 is a diagram illustrating an example of a sweeping pattern when a mask is used in acceleration or deacceleration areas of a laser light, in the present invention.

FIG. 7 is a diagram illustrating an example of a method of carrying out laser irradiation on a patterned light-absorbing layer, in the present invention.

FIG. 8 is a diagram illustrating a form when laser irradiation is carried out when a particulate light-absorbing body has been coated, in the present invention.

FIG. 9 is a diagram illustrating a case that an impurities-containing layer is used as a heat-transfer layer, in the present invention.

FIG. 10 is a diagram illustrating an example of a form of activating ion-implanted impurities.

FIG. 11 is a diagram illustrating an example of a method of carrying out laser irradiation while blowing inactive gas to a light-absorbing layer.

### BEST MODE FOR CARRYING OUT THE INVENTION

Below, with respect to an embodiment of the present invention, description will be made referring to drawings. However, the present invention is not limited to this.

FIG. 1 shows a schematic cross section of an example of a configuration concerning a heat-treating target body to which the heat-treating method of the present invention is carried out, and herein below, description will be made with respect to the embodiment of the heat-treating method of the present invention.

In this embodiment, in a heat-treating target body 1, for example a Si semiconductor layer is formed as a heat-treating target layer 3 on a substrate 2, for example a glass substrate, and a light-absorbing layer (also called a heating layer, the same applies herein below) 4 that is based on carbon is further formed thereupon. A heat-transfer layer of 5 nm-100 μm thick can intermediate between the light-absorbing layer 4 and the heat-treating target layer 3, which, however, is not shown in FIG. 1. When the combination of the light-absorbing layer 4 and the heat-treating target layer 3 is such as to increase reactivity under a high temperature, the heat-transfer layer can be caused to function as a barrier layer.

In the above-described heat-treating method, particularly when the method is applied to a device in which it is not desirable that carbon atoms that constitute the light-absorbing layer 4 diffuse to the heat-treating target layer 3 by being subjected to high temperatures, by providing a heat-transfer layer with the thickness of 5 nm or more between the heat-treating target layer 3 and the light-absorbing layer 4, there is a case of producing the effect that the diffusion is sufficiently suppressed. However, because the heat-transfer efficiency tends to decrease as a result of providing the heat-transfer layer, it is not desirable to make the heat-transfer layer unnecessarily thick. In the case of the present invention, if the thickness of the heat-transfer layer exceeds 100 μm, it will not function as the heat-transfer layer. When some diffusion of carbon to the heat-treating target layer is allowed, because emphasis is put on the heat-transfer efficiency, there is a case that the heat-transfer layer is omitted.

A semiconductor laser light 5 is caused to irradiate and sweep from the above. The ambient atmosphere at the time of irradiation may be normally the atmosphere of air. It is basically preferable that the semiconductor laser light is the CW (continuous wave oscillation) light. Particularly, the semiconductor laser in the range of 600 nm to 2 μm in wavelength is compact and cheap, and further, it is possible to integrate a large number of semiconductor laser devices like a bar-stacking type, etc. to easily obtain a light output of extremely high power. Accordingly, in contrast to that the output of an excimer laser appeared in the market in the past has been about 1 kW at the highest, it is the semiconductor laser that can basically output 10 to 100 times more than the excimer laser, and the irradiation light source can be configured using this. If a light source of such high power can be used, it is possible to form a light beam of a large area. Or, because it is possible to carry out beam sweeping at a high speed, heat-treating in a short period of time becomes possible. Further, the semiconductor laser has the characteristic that by controlling the current to be applied, a light output that is approximately in a linear relation with this current value is obtained and that it is the semiconductor laser source in which control of the light output is very easy. If it is a CW oscillation-type semiconductor laser, depending on the current waveform, it is also possible to obtain a pulse-like light output.

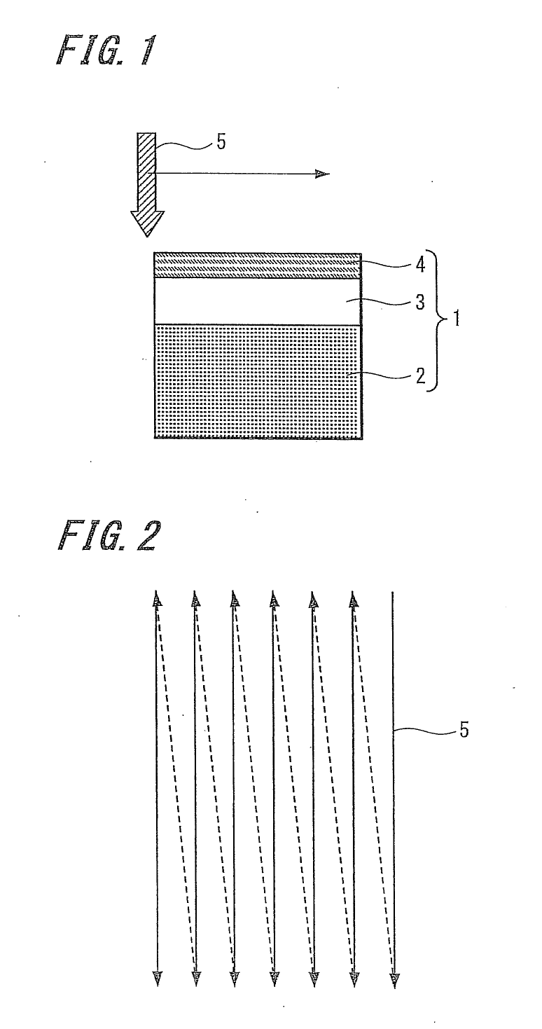

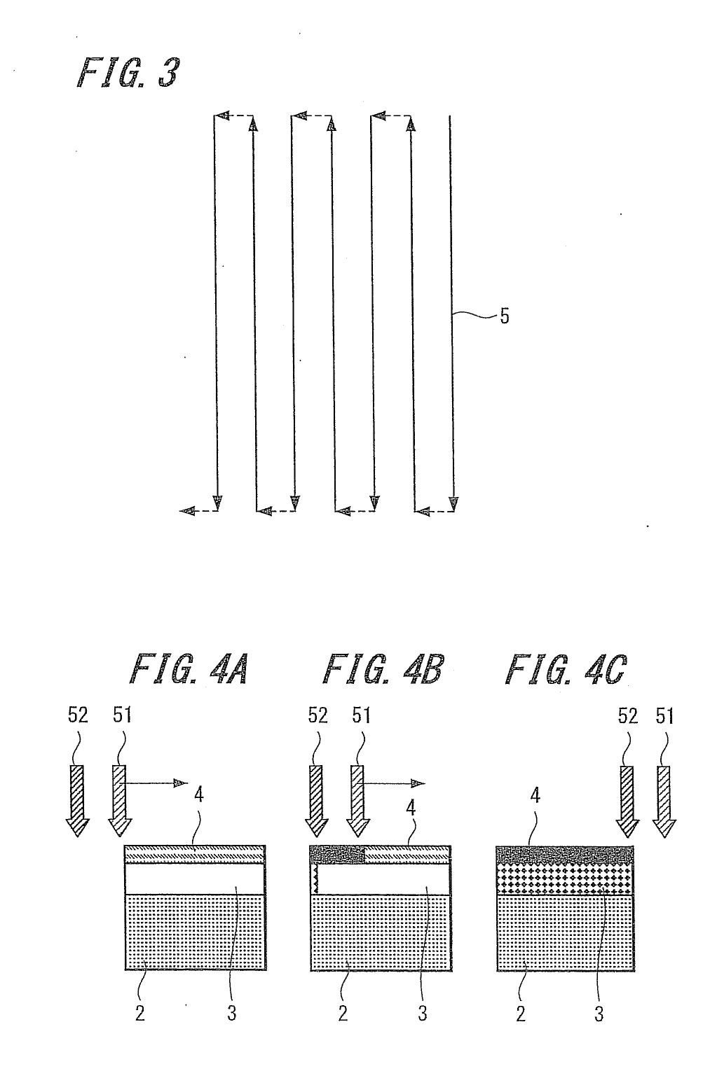

FIG. 2 and FIG. 3 respectively show examples of light beam sweeping methods. The solid line indicates a locus of positions where the beam intensity is at the peak. The semiconductor laser light heat-treats the heat-treating target part, while shifting the irradiation position by an appropriate beam sweeping mechanism. The dotted line portion is a locus portion where the light intensity has been modulated and the output has been decreased. Of course, as necessary, light irradiation can be carried out in the same manner in the dotted line portion. Also, in FIG. 2 and FIG. 3, in the points where the sweeping direction changes, the irradiation time becomes longer, so that it is desirable to control the intensity of the laser beam to be weakened before reaching such points.

The actual semiconductor laser light has a beam diameter of an infinite size even when the laser light is condensed by a predetermined optical system. Further, generally an intensity distribution exists within the beam, the light intensity being lower at the periphery part than the center part. By making the feed pitch of the beam sweeping line smaller than the beam diameter (width), that is, by beam sweeping with irradiated areas overlapped with each other, it becomes possible to homogenize the heat-treating effect to the heat-treating target part.

It is preferable that the irradiating semiconductor laser irradiates the same place of the light-absorbing layer 4 continuously for the time period of 100 ns or more, preferably, 100 ns-100 ms, for one sweeping. If the time period is shorter than 100 ns, only the light-absorbing layer becomes easy to be heated, and therefore, if the laser light intensity is increased to give sufficient heat transfer to the heat-treating target layer, there is the inconvenience such that the light-absorbing layer is easy to be ablated. If the time period is longer than 100 ms, the heat diffusion length becomes longer, and when the laser light intensity is weak, it becomes that the temperature of the heat-treating target layer will not rise to a predetermined temperature. When the laser light intensity is sufficiently strong and the temperature of the heat-treating target layer rises to the predetermined temperature, there occurs the inconvenience that even the other areas not desired to be heated are heated to the temperature close to that of the heat-treating target layer portion.

Heating for a short period of time by beam sweeping of a CW laser is different in quality from heating for a short period of time by a pulse laser in that by appropriately selecting the beam sweeping condition, a heating and cooling process that is too abrupt can be avoided due to the heat diffusion effect to adjacent parts that are not irradiated with the laser light. Especially, when heating the heat-treating target layer 3 to 1400° C. or more using the pulse laser with the pulse width smaller than 100 ns, such as an excimer laser, the inconvenience is easy to occur that ablation of the light-absorbing layer 4 is easy to take place. On the other hand, when a CW laser beam having an intensity distribution of Gaussian type is caused to sweep, the preceding skirt portion having a weak intensity starts to irradiate, and next, the portion having the maximum intensity is caused to irradiate, and then, the skirt portion having the weak intensity again irradiates. That is, although it is in the range of a short period of time such as 100 ns-100 ms, unlike pulse laser radiation, it is easy to control temperature rise and temperature fall, so that there is the characteristic that the inconvenience accompanying abrupt heating, such as ablation, etc., is hard to occur.

As one example, in a case that the light-absorbing layer 4 has the light absorbance of 40% at the wavelength of the irradiating semiconductor laser light 5, when the power of the semiconductor laser light 5 is controlled to be constant at 20 W and the laser beam diameter is narrowed down to 400 μm, a Si film having the film thickness of 50 nm has been phase-changed from an amorphous state to a polycrystalline state at the sweeping speed of 30 cm/s or below.

If the material of the substrate 2 has transparency to the wavelength of the semiconductor laser light 5, by causing the semiconductor laser light 5 to irradiate from the side of the substrate 2, the semiconductor laser light 5 passes through the substrate 2 and the heat-treating target layer 3 and the energy is efficiently absorbed only by the light-absorbing layer 4, the light-absorbing layer 4 generates heat, and with this heat, the heat-treating target layer 3 can be indirectly heat-treated.

Also, after completing light irradiation of a predetermined area once with the beam sweeping mechanism, it is possible to beam-sweep the same area to carry out heat-treating. Particularly, for example when the light-absorbing layer contains hydrogen, there is a case that it is desirable to adopt a method in which first, laser irradiation and sweeping at a low power density is carried out to outgas the hydrogen, and thereafter, laser sweeping is carried out at a high power density that is required in crystallization of the Si film. For example, if light irradiation at a high power density is carried out from the first to the light-absorbing layer 5 containing hydrogen, the hydrogen within the light-absorbing layer is abruptly erupted, so that there is a possibility that the light-absorbing layer 4 is destroyed by this impact, and due to this, it is likely to occur that heat transfer to the heat-treating target layer 3 is not effectively carried out. In such case, it is necessary to carry out beam sweeping for a repeating number of times, not only twice but also many more times.

FIG. 4 schematically shows a case that two semiconductor laser beams, a preceding semiconductor laser light 51 and a following semiconductor laser light 52, are arranged in the beam sweeping direction, and each irradiates the heat-treating target layer 3 one time by one beam sweeping, that is, laser irradiation is carried out two times in total. FIG. 4A shows a state before beam irradiation is carried out, FIG. 4B show a state that beam irradiation is being carried out, and FIG. 4C shows a state after beam irradiation has been carried out, respectively. Respective power densities of the semiconductor laser light 51 and the semiconductor laser light 52 are different, and first the light-absorbing layer 4 is reformed by beam irradiation of the preceding semiconductor laser light 51. For example, in the case of a carbon film containing hydrogen, by irradiation of the semiconductor laser light 51 having a beam of relatively low energy, the hydrogen is caused to outgas and the light absorbance changes. Next, the following semiconductor laser light 52 beam-irradiates. When the wavelength of the beam of the following semiconductor laser light 52 is set to the bandwidth where the light absorption by the light-absorbing layer whose light absorbance has been changed becomes large, the following semiconductor laser light 52 with high power is efficiently absorbed by the light-absorbing layer 4, and the light-absorbing layer is heated to a high temperature. Thereby, at a high efficiency, the heat-treating target layer 3 is heat-treated. When the heat-treating target layer 3 is an amorphous silicon in FIG. 4A, in FIG. 4C the heat-treating target layer 4 can be made a crystalline silicon.

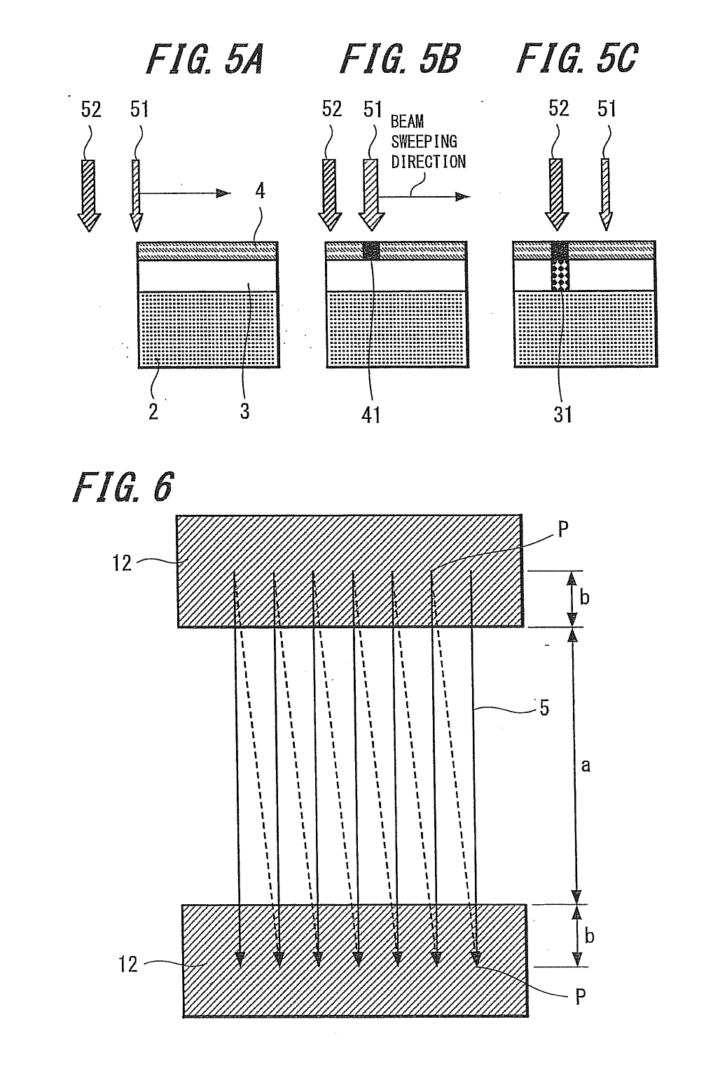

Next, description will be made using FIG. 5 with respect to an example of sweeping while controlling the intensity of a laser beam of the preceding semiconductor laser light 51. As illustrated in FIG. 5, when sweeping is carried out while controlling the beam of the semiconductor laser light 51 so as to be intensity-modulated depending on the irradiation position and keeping the intensity of the following semiconductor laser light 52 constant, it is possible to efficiently heat-treat only a desired portion of the heat-treating target layer. As illustrated in FIG. 5A, if the light-absorbing layer 4 is swept with the semiconductor laser light 51 with the intensity thereof weakened, the light absorption index of the light-absorbing layer 4 does not change, and therefore, the light-absorbing layer 4 will not be subjected to a high temperature even by beam irradiation of the semiconductor laser light 52, and the heat-treating target layer 3 will not be heat-treated. Then, if the intensity of the semiconductor laser light 52 is increased in the position shown in FIG. 5B, the light-absorbing layer 4 partly changes and a light-absorbing layer 41 in which the light absorbance has been improved is formed. Next, as illustrated in FIG. 5C, if the intensity of the semiconductor laser light 51 is weakened and the light-absorbing layer 41 is swept by the semiconductor laser light 52, the light-absorbing layer 41 efficiently absorbs the light of the semiconductor laser light 52 to be raised to a high temperature, and thereby when the heat-treating target layer 3 is an amorphous silicon, as a crystalline silicon 31, crystallization can be carried out only in a desired portion. The number of laser beams needs not be two, and it is possible to make it to a plural number of three or more according to the object.

In a system in which a plurality of laser beams are provided, the arrangement of semiconductor laser beams is not necessarily limited only to the case of being in parallel to the beam sweeping direction, and for example, the arrangement perpendicular to the beam sweeping direction is possible. In this case, it is possible to obtain the area of heat-treating portions that corresponds to the number of beams by one beam sweeping, and there is an effect in decreasing the heat-treating time period.

As a variation example of this, for example, it is possible to beam-shape a semiconductor laser light using a predetermined optical system so as to be a linear beam perpendicular to the beam sweeping direction. For example, shaping is possible by inputting a linear beam to a long and thin lens in a semi-cylindrical shape (cylindrical lens). Other optical systems for beam shaping can be freely selected.

In particular, in this case, by making short the width of the line beam in the beam sweeping direction and increasing the beam sweeping speed, it is possible to shorten the period of time the laser beam irradiates in a certain irradiation position. If the beam irradiation time becomes short in the same point, the ratio of heat that is transferred to the substrate side decreases, and heat-treating that is efficient in energy can be accomplished.

However, in the case of heating in a short period of time, for example the crystal grain size of Si that phase-shifts from an amorphous state to a polycrystalline state does not grow so much, and it has a tendency that the electric characteristic is inferior to the Si film with a large crystal grain size with respect to electromagnetic mobility, etc. Conversely, in the crystallized film, to form portions having different electric characteristics in desired positions, it is possible to adopt a method of changing the beam sweeping speed. For example, in the case of a thin film transistor array for a liquid crystal display, because a thin film transistor for a peripheral driver circuit requires crystal Si with high electron mobility, when heat-treating this portion, the laser beam is caused to sweep at a low speed. Also, because it is not necessary to increase the electron mobility of the Si film of switching transistors of pixels, the semiconductor laser light can be caused to sweep at a high speed is possible. Thus, it is possible to make the process time necessary for heat-treating short and optimum.

To narrow the width of a line beam in the beam sweeping direction, there is a method of condensing the beam in one direction by appropriate optical design, however, besides, a method of inserting various types of spatial modulation filters such as a mask having a slit-like opening and others between the semiconductor laser light source and the surface of the portion to be irradiated may be adopted. The filter may be of other types than the slit-type, and by making the laser beam to have an appropriate intensity distribution, when this semiconductor laser light is caused to sweep, it is possible to control the time change of the intensity of a laser light caused to irradiate a certain position.

Also, as the semiconductor laser beam light, it can be caused to irradiate the heating layer through a light-shielding mask such as to cover a part of the beam sweeping area. For example, the turn-around point in the sweeping direction of a laser beam (edge portion of a sweeping line) shown in FIG. 2 or FIG. 3 corresponds to the acceleration or deceleration area of the beam sweeping mechanism. Therefore, as illustrated in FIG. 6, as compared to a speed constant area a in the center, in an acceleration or deceleration area b, the sweeping speed decreases. At a turn-around point P, the sweeping speed is zero. Therefore, in this portion, the laser light irradiates with the energy density that is unnecessarily high. To avoid this, as illustrated in FIG. 6, it is possible to arrange a light-shielding mask 12 for avoiding the sweeping speed acceleration or deceleration area b, that is, the area where the sweeping speed changes, from being irradiated with the laser light and to cause the semiconductor laser light to irradiate in this state.

It is also possible to cause the semiconductor laser light to irradiate, with a part of the beam speed constant area a selectively shielded with a light-shielding mask. For example, this can be applied to the case of activation annealing after selectively carrying out deep ion implantation, etc.

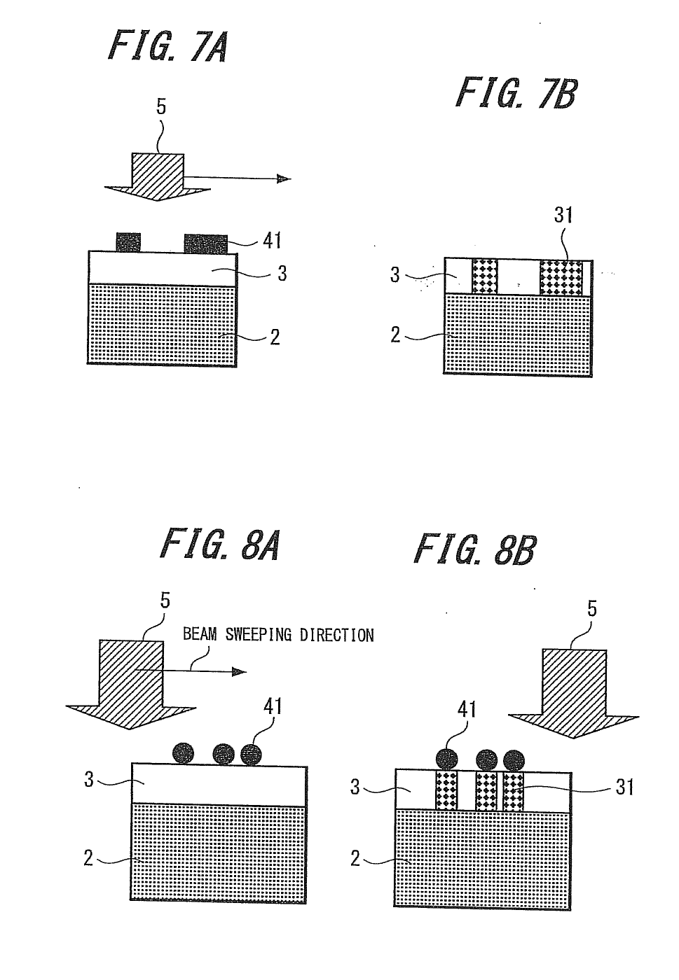

As the method of heat-treating only a desired portion in the heat-treating target layer 3, besides the above-described methods, there is the following method. FIG. 7 is a diagram for explaining one example thereof. As illustrated in FIG. 7A, with a known method, a light-absorbing layer 41 that has been patterned is obtained on the heat-treating target layer 3. Thereafter, the semiconductor laser light 51 is caused to sweep to heat-treat only a part of a heat-treating target layer 31 contacting the light-absorbing layer 41. Here, when the heat-treating target layer 3 is an amorphous Si film, only the portion 31 of the Si film that contacts the light-absorbing layer 41 is crystallized. There is no particular limitation to the patterning method of the light-absorbing layer 41. For example, when the light-absorbing layer 41 is a carbon film, when forming the carbon film, by placing a hard mask on the heat-treating target layer 3, it is possible to form the carbon film only in the opening of the hard mask, thus forming the pattern of the carbon film. It is also possible to obtain a carbon film subjected to a predetermined patterning, by carrying out etching with oxygen plasma through a mask formed by photolithography, etc., after forming a carbon film over the entire surface of the heat-treating target layer 3.

As the patterning method of the light-absorbing layer 4, a method in which the particulate material is used for forming the light-absorbing layer 4 can be adopted. The film formation method of the light-absorbing layer 4 is not limited. For example, as illustrated in FIG. 8A, carbon micro-particles are dispersed in an appropriate liquid solution, and by spin coating, the light-absorbing layer 4 can be formed in a film state on the heat-treating target layer 3. It can be carbon coating by an ink jet method in which ink is made by similarly dispersion stabilizing particulate carbon in an appropriate liquid solution. Because the carbon-dispersing element is coated while controlling the position of an ink jet nozzle, there is an advantage that in the above-described patterning of carbon, a mask is not particularly needed to be prepared.

When the particulate or powder material is coated to form a light-absorbing layer, if a pulse laser of an extreme short period of time having the pulse width of 100 ns or smaller like an excimer laser is caused to irradiate, a phenomenon like adiabatic ablation is caused, carbon particles are easily removed, and the inconvenience that heat is not sufficiently transferred to the heat-treating target layer occurs. However, as illustrated in FIG. 8B, like the present invention, when the semiconductor laser light of continuous-wave oscillation is used, because the output of a laser beam, the diameter of the beam, and the laser beam sweeping speed can be easily controlled, the irradiation time period can be easily controlled, and the condition for suppressing removal of the particulate light-absorbing layer can be easily found, and therefore, it becomes possible to heat-treat a desired position of the heat-treating target layer 31.

The irradiation of a semiconductor laser light is not limited to the irradiation from the opposite side of the substrate as illustrated in FIG. 1. For example, when the substrate has high transparency to the wavelength of a laser as the irradiating light, like a glass substrate, and if the light transparency of the heat-treating target layer is high, the semiconductor laser light may be caused to irradiate from the substrate side. For example, consider that the heat-treating target layer is a Si film, the Si film is crystallized by the heat-treating method of the present invention, and a thin film transistor is made using this crystallized film. When the light-absorbing layer is a carbon film, and further, the electric conductivity is extremely low, if a carbon film is formed immediately on a substrate, and an amorphous Si film as a heat-treating target layer is formed directly thereupon or through a heat-transfer layer of a predetermined film thickness, it is allowed to form a thin film transistor of top-gate type, after providing heat-treating of the present invention, in a state that the carbon film has been left as it is on the back channel side of the Si, without particularly removing it. A merit that it is possible to eliminate the etching process of carbon is produced. Of course, in this case also, laser irradiation can be performed not from the substrate side but from the side of the Si film serving as the heat-treating target layer. This is because that the Si film used in a thin film transistor is about 50 nm in thickness, and has hardly any absorption relative to the semiconductor laser light.

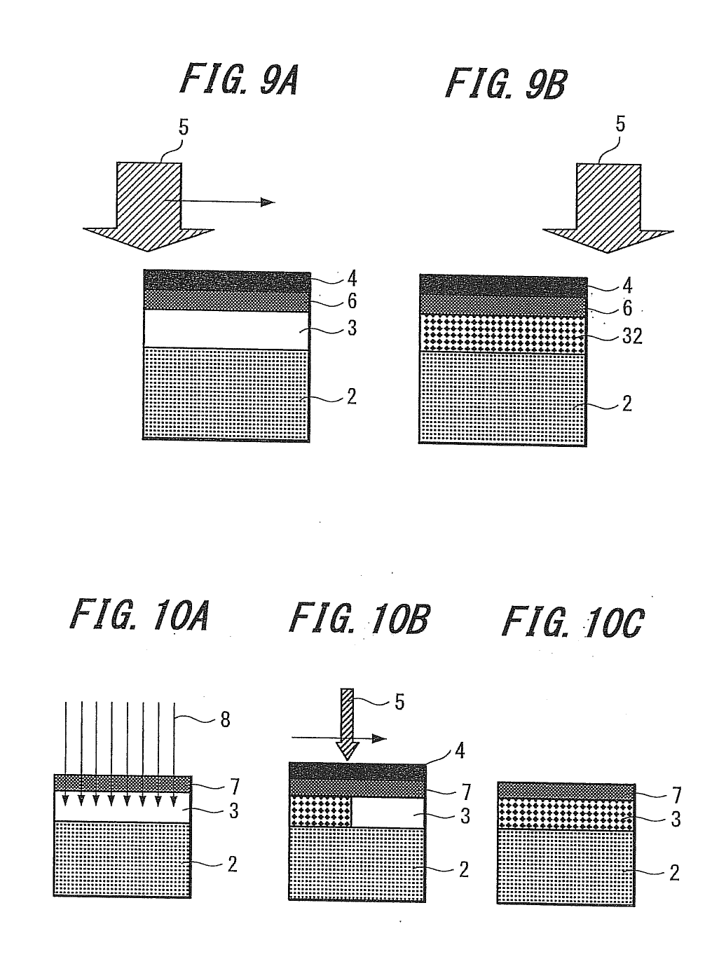

FIG. 9 is a diagram for explaining a method of doping impurities in which the heat-treating target layer 3 of the present invention is a semiconductor layer and impurities are doped into this. FIG. 9A shows a state before beam irradiation and FIG. 9B shows a state after completing beam irradiation, respectively. In this figure, if the semiconductor layer (heat-treating target layer 3) is Si, and the layer corresponding to a heat-transfer layer is an impurities containing layer 6 of PSG (phosphosilicate glass) or BSG (borosilicate glass), due to the present heat-treating, P or B is effectively diffused or activated in the Si film and valence electron control such that the Si film turns into an n or p type becomes possible. An area 32 is the Si film in which impurities have been doped. Control of impurities concentration and control of doping depth are also easy by control of the light intensity and beam sweeping condition. It is possible to make the thickness of the impurities containing layer 6 to 5 nm-100 μm. If the thickness is smaller than 5 nm, in the case of devices that dislike carbon contamination, the inconvenience that carbon diffuses to the heat-treating target layer 3 through the impurities containing layer 6 arises, and if the thickness exceeds 100 μm, the inconvenience that the heat produced in the light-absorbing layer cannot be sufficiently transferred to the heat-treating target layer 3 arises.

It is needless to say that the material of the semiconductor layer and impurities containing layer is not limited to these.

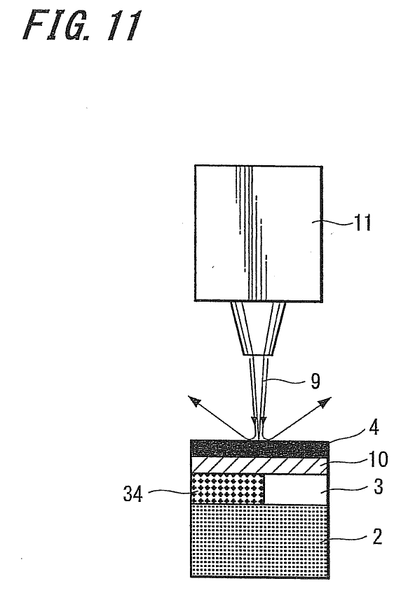

As the other method of doping impurities in which the heat-treating target layer is a semiconductor layer and impurities are doped into this, there is also a method of doping by ion implantation. FIG. 10 illustrates an example for explaining this. In this figure, an example is shown in which the semiconductor layer is Si, and the layer corresponding to the heat-transfer layer is SiO₂ that is generally called a screen oxide film 7. In this example, gas that includes appropriate atom of impurities is ionized by plasma decomposition, and this ion species 8 is accelerated by voltage application of 100-several hundreds kV to be implanted into the semiconductor layer 3 (see FIG. 10A). For example, if the gas is BF₃ gas, it is decomposed to BF₂ ion, and B atom is implanted, and if the gas is PH₃, it is decomposed to PHx ion, and P atom is implanted.

In recent years, with miniaturization of MOS transistors, the demand for suppressing the thickness of an ion-implanting layer up to about 10 nm is starting to come up. Therefore, a method is being tried that makes the acceleration voltage to 10 kV or lower and the ion-implanting layer shallow by providing the screen oxide film having the thickness of about 5-10 nm. If ion implantation is carried out, crystallization of the semiconductor layer into which ion species have been implanted by a high acceleration voltage is broken, and because binding of impurities atoms and semiconductor atoms is insufficient, and if nothing is done, it will not become an electrically low-resistivity layer. Consequently, heat-treating for activating impurities is necessary. The present invention can be applied to this heat-treating.

As a concrete example, the screen oxide film 7 is left as it is as a heat-transfer layer for suppressing carbon diffusion to the doping layer, and in the state that the screen oxide film has been left, a carbon layer that is a light-absorbing layer is formed thereupon 200 nm thick, and is irradiated with a laser. As the laser irradiation condition, a CW laser light having the wavelength of 940 nm, the beam diameter of 180 μm, and the peak power density of 80 kW/cm² is caused to beam-sweep at a speed of 7 cm/s. Thereafter, the carbon film is etched, and further, the screen oxide film 7 has been removed. Under this condition, the majority of the impurities atoms that have been ion-implanted is activated (activation ratio is nearly 100%), and the density distribution measurement in the depth direction of the impurities by a SIMS (secondary ion mass spectroscopy) having been carried out, it has been found that the density distribution of the impurities atoms stayed about the same as before the laser irradiation, and the diffusion length has been suppressed to 3 nm or below. That is, it has been found that the heat-treating method of the present invention is suitable as impurities activation annealing for forming a shallow source drain binding for miniature MOS devices.

Note that ion implantation is carried out not only for the valence electron control as above, there is a case of implanting the same 14 group elements such as Ge, Si, C, etc. to the Si substrate. For example, in MOS transistors, for the purpose of carrying out activation annealing at a low temperature as much as possible for suppressing impurities diffusion, there is a case that ion implantation is carried out for amorphization that precedes junction formation. Also, in the case of high density implantation of Ge or C into gates and channel portions of a MOS device, there is a case that it is intended to cause lattice distortion in the Si crystal of a mother body to increase the mobility of carriers. There is an effect that when distortion is caused in the direction increasing the lattice constant of channel portions, the electron mobility is increased and when distortion is caused in the direction of decreasing the lattice constant, the hole mobility is increased. When carrying out ion implantation for these purposes also, it becomes necessary to carry out heat-treating for recovering crystallinity. The heat-treating method of the present invention can be carried out for the purpose of re-crystallization annealing for recovering crystallinity.

Thus, the heat-treating method of the present invention can be applied to a so-called post-annealing process after ion implantation, such as activation of impurities after ion implantation, recovering of crystallinity of the semiconductor layer after ion implantation, etc.

According to the heat-treating method of the present invention, unlike an extremely short pulse laser such as an excimer laser, it is easy to make the heating time period of a heat-treating target layer longer. For example, when the heat-treating target layer is a semiconductor, and a crystallized film is obtained through a melt-solidification process by the present heat-treating, the cooling speed of the heat-treating target layer is easy to control, and thereby control of the crystal grain size becomes easy. At this time, by temperature controlling the heat-treating target layer by a means that is different from the semiconductor laser light, the cooling speed in the solidification process of the heat-treating target layer can be additionally controlled. For example, by carrying out additional heating by a heater at a temperature of about 100° C.-300° C., the cooling speed can be further decreased, and an effect of making the crystal grain large is produced.

On the other hand, by decreasing the beam sweeping speed, a tendency is caused that the ratio of the thermal energy dissipated to the substrate side increases, and in particular, when it is necessary to select for the substrate a material having no heat resistance, the possibility may occur, due to the heat-treating of the present invention, that the inconvenience that there is a case of giving heat damage to the substrate side is caused. Therefore, a need may arise to suppress heat damage by causing the substrate to contact a cooling body such as a Peltier element.

As above, as the semiconductor laser light source, description has been made with a central focus on a CW semiconductor laser, however, of course, it is not limited to this. For example, it can be a solid laser, such as an Nd:YAG laser, in which a CW semiconductor laser is the excitation light source, and others, and it can be a fiber laser also in which a CW semiconductor laser is the excitation light source.

The mechanism and method for beam sweeping is not also limited.

For example, it may be such that a condensing optical system and a semiconductor laser constitute an integrated light source unit and this light source unit is mounted on a movable XYZ stage and is caused to beam sweep on a heat-treating target body which has been fixed, and a method may be adopted in which a laser as the light source and a heat-treating target body are fixed and a semiconductor laser light is caused to sweep and irradiate the heat-treating target body by a beam sweeping optical system constituted for example by a galvanometer mirror and an f θ lens. Also, it may be a method in which although the laser is fixed, an optical fiber in which a semiconductor laser light is introduced and a light condensing optical system are mounted on a movable XYZ stage, and the semiconductor laser light is cause to weep and irradiate a fixed heat-treating target body. Conversely, a method may be such that the light source is fixed, however, the heat-treating target body is mounted on an XY stage.

Note that in the above-described description on the embodiment of the present invention, it has been described as that the atmosphere when a laser is caused to irradiate can be the air atmosphere, however, it is not particularly limited to this. The reason that the atmosphere can be the air atmosphere is that although the normal heat resistance temperature of carbon is 300° C. or below, during laser irradiation of an extremely short time period, there is very little effect that oxygen and carbon in the air are oxidized by chemical reaction and film decreasing occurs. However, there is a case in the strong laser light irradiation that slight decrease in the carbon film may still cause lowering of the light absorption index. In particular, it is considered that when the same place is multiply irradiated, a change of the light absorbance is not desirable. In this case, control of the atmosphere at the time of laser irradiation becomes necessary. Generally, the heat-treating target sample is often put in a chamber in a state that appropriate vacuum or inactive gas has been encapsulated or is always flown, and in this state, laser is caused to irradiate through a quartz window.

Also, as illustrated in FIG. 11, laser may be caused to irradiate even in the atmosphere open state while blowing a strong inactive gas 9 from an inactive gas supplying unit 11 to the vicinity of a laser-irradiated part. Due to inactive gas irradiation at a sufficient flow rate, the oxygen gas component in the atmosphere is replaced with the inactive gas 9, and the oxidation reaction of carbon serving as the light-absorbing layer 4 can be suppressed. As the inactive gas 9, N₂ gas, argon gas, helium gas, or mixed gas of these can be used, however, it is not limited to these, and any gas that has an effect of sufficiently suppressing oxidation of carbon can be used. Note that in FIG. 11, a heat-transfer layer 10 is illustrated between the heat-treating target layer 3 and the light-absorbing layer 4. The heat-treating target layer 3 is a so-called untreated area, and an area 34 is the area after having been heat-treated.

### EXPLANATION OF REFERENCE NUMERALS

1: heat-treating target body, 2: substrate, 3, 31: heat-treating target layer, 4, 41: light-absorbing layer, 32: impurities-doped Si film, 5, 51, 52: semiconductor laser light, 6: impurities-containing layer, 7: screen oxide film, 8: ion species, 9: inactive gas, 10: heat-transfer layer, 34: area after having been heat-treated, 11: gas supplying unit

1. A method of heat-treating a semiconductor in which a semiconductor laser light in a range of wavelength of 600 nm-2 μm is caused to irradiate a heating layer constituted of a carbon layer or layer including carbon that produces heat by absorbing light energy, to cause the heating layer to produce heat to heat-treat a semiconductor material contacting the heating layer directly or through a heat-transfer layer of 5 nm-100 μm in thickness,
wherein the semiconductor laser light is caused to continuously irradiate a same place of the heating layer for a time period of 10 ns-100 ms for one sweeping, and
wherein the semiconductor laser light is caused to repeatedly sweep and irradiate a place to be swept and irradiated so that the place to be swept and irradiated has a partial overlap.

2. The method of heat-treating a semiconductor described in claim 1, wherein the semiconductor laser light is caused to sweep and irradiate with a light intensity thereof controlled.

3. A method of heat-treating a semiconductor in which a semiconductor laser light in a range of wavelength of 600 nm-2 μm is caused to irradiate a heating layer constituted of a carbon layer or layer including carbon that produces heat by absorbing light energy, to cause the heating layer to produce heat to heat-treat a semiconductor material contacting the heating layer directly or through a heat-transfer layer of 5 nm-100 μm in thickness,
wherein the semiconductor laser light is caused to continuously irradiate a same place of the heating layer for a time period of 10 ns-100 ms for one sweeping, and
wherein a same place is repeatedly swept with a light intensity of an irradiating semiconductor laser light changed.

4. A method of heat-treating a semiconductor in which a semiconductor laser light in a range of wavelength of 600 nm-2 μm is caused to irradiate a heating layer constituted of a carbon layer or layer including carbon that produces heat by absorbing light energy, to cause the heating layer to produce heat to heat-treat a semiconductor material contacting the heating layer directly or through a heat-transfer layer of 5 nm-100 μm in thickness,
wherein the semiconductor laser light consisting of a plurality of beams is caused to sweep and irradiate.

5. The method of heat-treating a semiconductor described in claim 4, wherein the semiconductor laser light consisting of a plurality of beams is arranged in a same direction as a beam sweeping direction, and light intensities of the plurality of beams are differentiated and a same place is sequentially irradiated with laser beams of different intensities.

6. The method of heat-treating a semiconductor described in claim 5, wherein an intensity of a beam irradiating first is weaker than an intensity of a beam irradiating later.

7. The method of heat-treating a semiconductor described in claim 4, wherein the semiconductor laser light consisting of a plurality of beams is arranged perpendicularly to a beam sweeping direction.

8. The method of heat-treating a semiconductor described in claim 7, wherein the semiconductor laser light is beam-shaped by a predetermined optical system so as to be a linear beam perpendicularly to the beam sweeping direction.

9. The method of heat-treating a semiconductor described in claim 1, wherein the semiconductor laser light is caused to irradiate the heating layer through a filter of spatial modulation type or a light shielding mask covering a part of a beam sweeping area.

10. The method of heat-treating a semiconductor described in claim 1, further comprising forming the heating layer consisting of a carbon layer or a layer including carbon in a pattern shape on the semiconductor material.

11. The method of heat-treating a semiconductor described in claim 1, wherein raw materials forming the carbon layer or layer including carbon are in a particulate form.

12. The method of heat-treating a semiconductor described in claim 1, wherein the semiconductor material is formed in a substrate formed of a material having transparency relative to an irradiation light source, and the semiconductor laser light is caused to irradiate from the substrate side.

13. A method of heat-treating a semiconductor, wherein a semiconductor laser light in a range of wavelength of 600 nm-2 μm is caused to irradiate a heating layer constituted of a carbon layer or layer including carbon that produces heat by absorbing light energy, to cause the heating layer to produce heat to heat-treat a semiconductor material through an impurities containing layer of 5 nm-100 μm in thickness contacting the heating layer, and the semiconductor laser light is caused to irradiate a same place of the heating layer continuously for a time period of 100 ns-100 ms.

14. The method of heat-treating a semiconductor described in claim 1, wherein the semiconductor material is temperature-controlled by a heating or cooling means that is separate from the laser irradiation.

15. The method of heat-treating a semiconductor described in claim 13, wherein the semiconductor material is temperature-controlled by a heating or cooling means that is separate from the laser irradiation.

16. The method of heat-treating a semiconductor described in claim 1, wherein at a time of the laser light irradiation, inactive gas is blown to a surface of the carbon layer that produces heat by absorbing light energy.

17. The method of heat-treating a semiconductor described in claim 13, wherein at a time of the laser light irradiation, inactive gas is blown to a surface of the carbon layer that produces heat by absorbing light energy.

18. The method of heat-treating a semiconductor described in claim 1, wherein heat-treating to the semiconductor material is a post-annealing process after ion implanting impurities into the semiconductor material.
